(19) United States
(12) Patent Application Publication
(10) Pub. No.: US 2009/0217963 A1
(43) Pub. Date: Sep. 3, 2009

(54) PHOTOVOLTAIC APPARATUS FOR CHARGING A PORTABLE ELECTRONIC DEVICE AND METHOD FOR MAKING

(75) Inventors: Yong Liang, Gilbert, AZ (US); Kurt W. Eisenbeiser, Tempe, AZ (US); Allison M. Fisher, Chandler, AZ (US); Ramkumar Krishnan, Gilbert, AZ (US)

Correspondence Address: INGRASSIA FISHER & LORENZ, P.C. (MOT), 7010 E. Cochise Road, SCOTTSDALE, AZ, 85253, US

(73) Assignee: MOTOROLA, INC., Schaumburg, IL (US)

(21) Appl. No.: 12/040,259

(22) Filed: Feb. 29, 2008

(51) Int. Cl. H01L 31/18; H01L 31/0224

(52) U.S. Cl. 136/243; 438/85; 427/74; 257/E31.126

(57) ABSTRACT

A method of making a plurality of photovoltaic cells (400, 800, 1112) for charging a battery (1230) of an electronic device (1010) includes forming by a self-assembly process a plurality of interdigitated photovoltaic cells (400, 800, 1112) between two terminal electrodes (102, 202, 132, 232) coupled to the battery (1230). One electrode is a transport conductive material (102, 202) including a conductive material (106, 206) having sidewalls (110, 210) defining a plurality of pores (112). A conductive electrode material (126, 226) is formed over an electrolyte (124, 224) which is formed over a sensitizing material (122, 222) which is formed over an active transport material (114, 214) on the sidewalls (110, 210).

### FIELD

The present invention generally relates to portable electronic devices and more particularly to photovoltaic cells for charging a portable electronic device and a method for making the photovoltaic cells.

### BACKGROUND

The market for personal portable electronic devices, for example, cell phones, laptop computers, personal digital assistants (PDAs), digital cameras, and music playback devices (MP3), is very competitive. Manufacturers, distributors, service providers, and third party providers have all attempted to find features that appeal to the consumer. For example, manufacturers are constantly improving their product with each model in the hopes it will appeal to the consumer more than a competitor's product. Battery life is one area in which improvements are sought.

Rechargeable batteries are currently the primary power source for cell phones and various other portable electronic devices. The energy stored in the batteries is limited. Energy storage is determined by the energy density (Wh/L) of the storage material, its chemistry, and the volume of the battery. For example, a typical Li ion cell phone battery with a 250 Wh/L energy density, and a 10 cc battery would store 2.5 Wh of energy. Depending upon usage, the energy could last for a few hours to a few days. Recharging often requires access to an electrical outlet. The limited amount of stored energy and the frequent recharging are major inconveniences associated with batteries. Accordingly, there is a need for longer lasting cell phone power sources that are recharged easily. One approach to fulfill this need is to have a hybrid power source with a rechargeable battery and a method to trickle-charge the battery. Important considerations for an energy conversion device to recharge the battery include power density, size, and the efficiency of energy conversion.

Energy harvesting methods such as solar cells, thermoelectric generators using a temperature gradient, and mechanical/kinetic generators using mechanical motion are very attractive power sources to trickle charge a battery. However, the energy generated by these methods is often small, usually only a few milliwatts to approximately a few hundred milliwatts depending on size, efficiency, nature of the energy source, etc. In the regime of interest, namely, a few hundred milliwatts to a few watts, this dictates that a sizeable volume or area is required to generate sufficient power for trickle charge. Such methods include coupling the battery to a solar panel (photovoltaic cell). See for example, U.S. Pat. No. 5,898,932 issued on 27 Apr. 1999.

Photovoltaic cells are well known for providing electricity from solar panels in both small scale distributed power systems and centralized megawatt scale power plants. Photovoltaic cells also have found applications in consumer electronics, e.g., portable electronic equipment such as calculators and watches. The cells operate without toxic or noise emissions, and require little maintenance. These cells may also be used as sensors for detection of a wide band of radiation.

Photovoltaic cells originally developed by the Bell Telephone Laboratories in the 1950's were, and most of the larger cells produced today are, crystalline silicon based because of the availability of high quality silicon which is produced in large quantities by the semiconductor industry. Amorphous silicon may be found in low power sources in portable electronic devices, even though solar conversion efficiency is limited.

There are several key issues in the use of photovoltaic (PV) cells for portable applications. These issues include cost, robustness, stability, toxicity of materials used, and efficiency (for example, electron transport).

Accordingly, it is desirable to provide an apparatus for charging a battery of a portable electronic device efficiently. Furthermore, other desirable features and characteristics of the present invention will become apparent from the subsequent detailed description and the appended claims, taken in conjunction with the accompanying drawings and this background.

### BRIEF DESCRIPTION OF THE DRAWINGS

Embodiments of the present invention will hereinafter be described in conjunction with the following drawing figures, wherein like numerals denote like elements, and

FIGS. 1-4 are cross sectional views of the exemplary embodiment illustrating fabrication process steps;

FIG. 5 is a top view of the exemplary embodiment of FIG. 4 taken along line 5-5;

FIG. 6-7 are cross sectional views of another exemplary embodiment illustrating fabrication process steps;

FIG. 8 is a top view of the exemplary embodiment of FIG. 7 taken along line 8-8;

FIG. 9 is a flow chart of the process steps for fabricating the exemplary embodiment;

FIG. 10 is an isometric view of a portable communication device configured to incorporate the exemplary embodiments;

FIG. 11 is an isometric back view of the portable communication device taken along line 11-11 of FIG. 10 and in accordance with an exemplary embodiment;

FIG. 12 is a block diagram of one possible portable communication device of FIG. 10.

### DETAILED DESCRIPTION

The following detailed description is merely exemplary in nature and is not intended to limit the invention or the application and uses of the invention. Furthermore, there is no intention to be bound by any theory presented in the preceding background or the following detailed description.

Using a photovoltaic cell to trickle-charge the portable electronic device battery is attractive because it extends the battery life and enables emergency use of the phone in situations when the portable electronic device battery is depleted and the outlet charging capability is not readily available. Additionally, using a photovoltaic cell for trickle charging the portable electronic device battery may also find use in situation when power from the electrical grid is not available in the developing countries. However, one of the most important issues in photovoltaic cells is the transport of electrons and holes upon photo-excitation. For example, in the traditional dye-sensitized photovoltaic technology, the photo-excited electrons have to migrate on an average of several micron-meters in the porous TiO₂ layer before reaching the electrodes. As such, the probability of those electrons recombining with holes is high. In order to improve the efficiency, the transport of photo-excited electrons needs to be improved.

The exemplary embodiment described herein overcomes electron/hole transport efficiency issues found in the dye-sensitized photovoltaic cells. When feature sizes ranging from nanometers to micrometers, volumetrically interdigitated electrodes reduce distances between electrodes significantly, resulting in improved electron/hole transport. Dry or wet processes, or a combination thereof, may be used in the exemplary self-assembly process. The self-assembly manufacturing process is cost effective compared to lithographic methods. The interdigitated electrodes may also help to guide light deep in the cells in addition to conducting charges, thereby improving optical absorption efficiency.

One exemplary embodiment of the photovoltaic cell includes the interdigitated electrodes formed by anodizing a material such as a layer of tin metal foil formed on a substrate (bottom electrode), which is preferably conducting, to create a porous non-absorptive conducting layer (for example, tin oxide or fluorinated tin oxide) having a plurality of fingers defining a plurality of pores, or cavities, having sidewalls over either a layer of active charge transport material, for example, an oxide such as titanium oxide or zinc oxide. An insulating material, for example, silicon oxide, magnesium oxide, or aluminum oxide, is formed over the tin oxide covering the conducting and active transparent materials while exposing the pores. The active charge transport material on the sidewalls is then coated with a sensitizer material, for example dye molecules and/or Quantum dots, for absorbing light and creating electron/hole pairs. The sensitizer material is then coated with an electrolyte material, for example a polymer based electrolyte, and the space remaining within the pores is filed with a conducting electrode material, which may be either transparent or non-light absorbing, having catalyst particles embedded therein, for example, indium tin oxide nano-particles mixed with a small amount of platinum particles either by layering or by uniformly mixing the two. A capping electrode material, for example, indium tin oxide, is formed over the insulating material and the top of the sensitizer material, the electrolyte material, and the transparent conducting electrode material within the pores. Light enters the photovoltaic cell through either the top or bottom electrode, or both sides, and/or the electrode material, and impacts the sensitizer material. A voltage appears across, and a current flows from, the capping electrode material and the bottom electrode.

While the above described exemplary embodiment forms layers from the conducting material towards the center of the pore, another exemplary embodiment includes forming the conducting material as a post and forming the layers on and away from the post.

FIGS. 1-5 describe the process steps for forming the photovoltaic cell in accordance with the exemplary embodiment. Referring to FIG. 1, a conductive material 102 is formed on a substrate 104 and anodized to form a plurality of fingers 106 having a top surface 108 and sidewalls 110 defining a plurality of pores 112. While the shape of the pores is shown as cylindrical (circular), it should be understood the shape may comprise any shape, for example, square or rectangular, and the size and shape of the pores can be optionally changed by chemical etching and/or other patterning methods. The substrate 104 may be transparent and may be conductive. After anodization, in which the treatment material 102 is oxidized, it becomes a conductive material. Optionally, after the anodizing step, a chemical treatment step may be carried out to enhance the conductivity of the anodized oxide. When anodized and treated, the fingers 106 comprise an oxide, preferably tin oxide, doped tin oxide, or indium tin oxide.

The sidewalls 110 are coated with an active transport material 114 such as titanium oxide or zinc oxide. The active transport material 114 formed may have a thin film morphology with smooth or rough surface, or a particle morphology with particle size ranging from 1 nm to 50 nm, or a combination of both. The active transport material 114 may be formed by vapor phase (such as Atomic layer deposition, CVD), chemical (such as layer-by-layer, sol-gel) or electrochemical (such as electrodeposition, and electrophoretic) deposition methods, preferably by immersing the structure 100 in a solution with oxide precursors for a period of time.

An insulating layer 116 (FIG. 2) is formed on the top surface 108 of the fingers 106 and the exposed top portion 118 of the active transport material 114. The insulating layer 116 may be, for example, silicon oxide, aluminum oxide, and magnesium oxide. The structure 200 is immersed in another solution to coat a sensitizer material 122 on the active transport material 114. Alternatively, the sensitizer material 122 may also be coated by vapor phase processes. The sensitizer material 122 is a material that converts light for generating electron/hole pairs.

The sensitizer material 122 is preferably organic dye molecules and/or quantum dots, which are sometimes called semiconductor nanocrystallites, whose radii are smaller than the bulk exciton Bohr radius and constitute a class of materials intermediate between molecular and bulk forms of matter. The organic molecules and quantum dots efficiently absorb light, e.g., sun light, and generate electron/hole pairs upon light absorption, they can also be dissolved into various solutions prior to being applied to the structure 200. The sensitizer layer 122 is formed on the active transport layer 114, preferably by, but not limited to, immersing the structure 200 in a solution containing dye complexes and/or quantum dots. The time of immersion can vary from a few minutes to a few days depending on temperature and solution concentration. The dye molecules can be ruthenium complexes where one of the ligands is typically 4,4′-dicarboxy-2,2′-bipyridyl. The quantum dots may be groups of II-VI, III-V, IV, or IV-VI materials, for example, CdS, CdSe, CdTe, ZnS, ZnSe, ZnTe, GaAs, GaP, GaAs, GaSb, HgS, HgSe, HgTe, InAs, InP, InSb, AlAs, AlP, AlSb. Alternative quantum dots that may be used include but are not limited to tertiary microcrystals such as InGaP and ZnSeTe, ZnCdS, ZnCdSe, and CdSeS. Multi-core structures are also possible such as ZnSe/ZnXS/ZnS, where X represents Ag, Sr, Te, Cu, or Mn. The inner most core is made of ZnSe, followed by the second core layer of ZnXS, completed by an external shell made of ZnS.

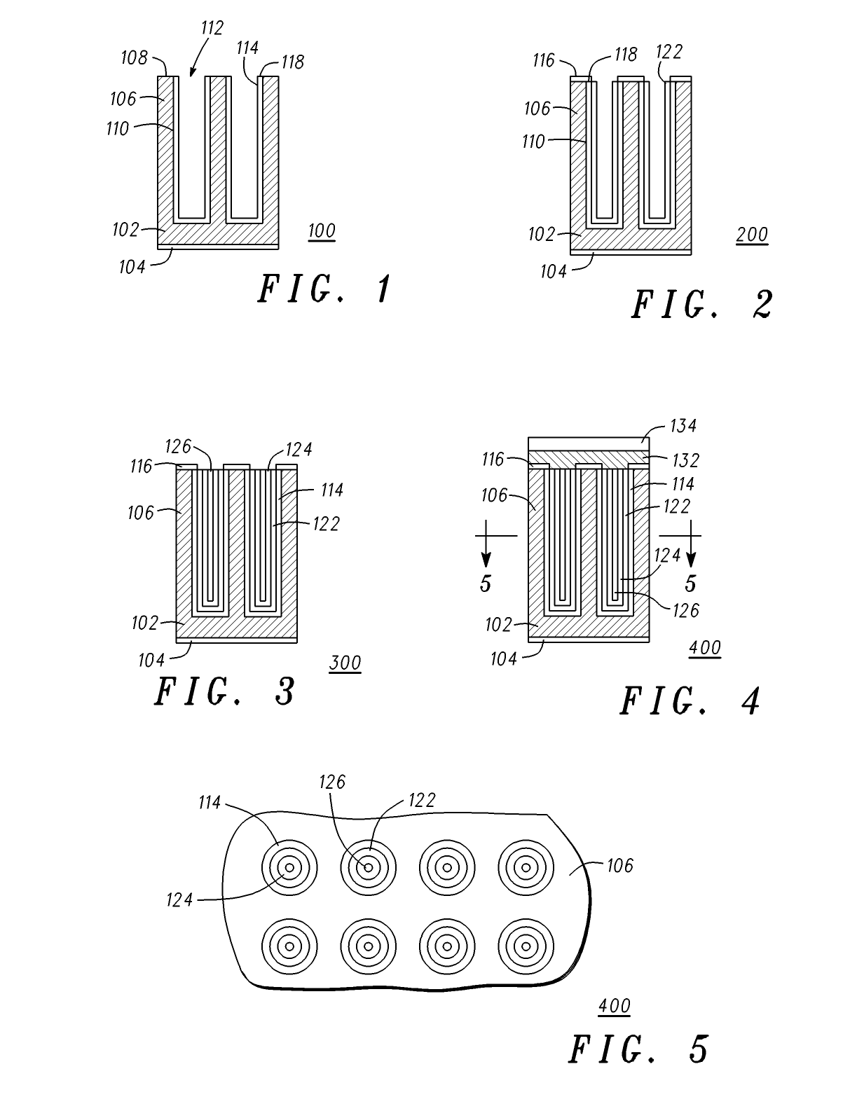

The structure 200 is then immersed in a solution to coat the sensitizer material 122 with an electrolyte material 124 (FIG. 3). Alternatively, the thin electrolyte layer 124 can also be formed on the sensitizer material using the vapor-phase based processes. The remaining area of the pores 112 is then filled with a material 126 comprising a conductive electrode material that is either transparent or non-absorbing to light (non-light absorbing) and a small amount of catalysts used for electrochemical reactions. In the preceding steps, any of the active transparent material 114, sensitizer material 122, electrolyte material 124, and mixture of transparent conductive electrode material and catalysts (126) forming on the top surface 108 or insulating layer 116 may be removed in any manner known in the industry, such as applying an ion beam at a grazing angle to strike the undesired accumulation. The electrolyte material 124 may be, for example, an electrolyte gel such as the ionic liquid electrolyte gels described by Wang, et al. (Chem. Commun. 2002, 2972-2973), or a polymer gel electrolyte with or without metal oxide nanoparticles fillers such as described by Akhtar et al. (IEEE Proceedings, 2006, 1568-1571), or sol-gel based electrolyte gels such as described by An et al. (Electrochem. Commun. 2006, 8(1), 170-172) and Joseph, et al. (Semiconductor Sci. and Technol. 2006, 21, 697-701). The transparent conductive electrode material 126 may be, for example, indium tin oxide, doped tin oxide or other forms of transparent conducting materials. The catalyst can be platinum, carbon, mixture of platinum and carbon, for example, but preferably is platinum nano-particles.

A capping electrode material 132 is formed over the insulating material 116 and the exposed sensitizer material 122, electrolyte material 124, and conductive electrode material and catalyst 126. The capping electrode material 132 may comprise any conductive material; however, preferably is transparent indium tin oxide. An optional protective layer 134 may be formed over the capping electrode material 132. The protective layer 134 may be, for example, glass or a transparent polymer with anti-reflective property. FIG. 5 is a top view of the structure photovoltaic cell 400 taken along the lines 5-5 of FIG. 4. Although there are only eight photovoltaic cells shown, it is understood there may be many more in one device.

In this exemplary embodiment, the active transport material 114, electrolyte material 124, and mixture of conductive electrode material and catalyst 126, and one or both of the conductive material 102 (including the substrate 104) and the capping electrode material 132 (including the protective layer 134) are formed as a transparent or non-light absorbing material. In operation, the photovoltaic cell is exposed to light, or radiation which may be outside of the visible spectrum. Light enters the structure 400 through either or both the transparent conductive material 102 (including the optional substrate 104) and the capping electrode material 132 (including the optional protective layer 134). This light passes through the conductive electrode material 126 and the electrolyte material 124 to strike the sensitizer material 122, creating electron/hole pairs. The electrons migrate to the conductive material 102 via the active transport material 114, while the holes migrate to the capping electrode material 132 via the electrolyte material 124 and the conductive electrode material 126. The transparent conductive materials 106 and 126 formed in this manner provide a volumetrically interdigitated structure.

In another exemplary embodiment, the substrate 104 or protective layer 134 is opaque so that light and radiation enter only from one side of structure 400.

In yet another exemplary embodiment, the polymer-based electrolyte 124 is replaced by a sacrificial layer of polymer that serves as a spacer layer between the sensitizer material 122 and the transparent conducting electrode material 126. The sacrificial polymer layer provides the space necessary for the electrolyte. Upon completion of the filling the transparent or non-light absorbing conducting electrode material 126 inside the pores, the sacrificial polymer layer is replaced by electrolyte through an exchange process.

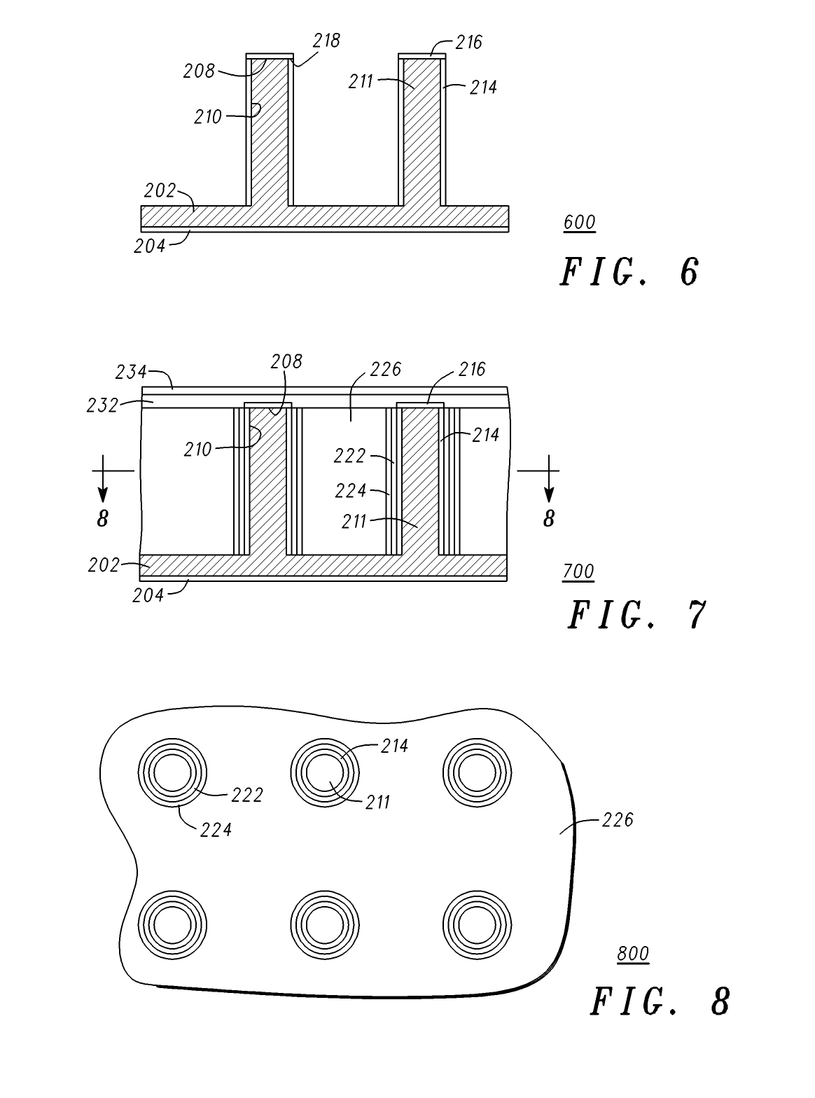

Referring to FIG. 6, in still another embodiment, a conductive material 202 is formed on a substrate 204 to form a top surface 208 and sidewalls 210 defining a plurality of posts 211. While the shape of the posts 211 is shown as cylindrical (circular), it should be understood the shape may comprise any shape, for example, square or rectangular, and the size and shape of the posts can be optionally changed by chemical etching and/or other patterning methods. The substrate 204 may be transparent and may be conducting. After an oxidation treatment, material 202 becomes a transparent or non-light absorbing conductive material. Optionally, after the oxidation step, a chemical treatment step may be carried out to enhance the conductivity of the oxide. When oxidized and treated, the posts 211 comprise an oxide, preferably tin oxide, doped tin oxide, or indium tin oxide.

The sidewalls 210 are coated with an active transport material 214 such as titanium oxide or zinc oxide. The active transport material 214 formed may have a thin film morphology with smooth or rough surface, or a particle morphology with particle size ranging from 1 nm to 50 nm, or a combination of both. The active transport material 214 may be formed by vapor phase (such as Atomic layer deposition, CVD), chemical (such as layer-by-layer, sol-gel) or electrochemical (such as electrodeposition, and electrophoretic) deposition methods, preferably by immersing the structure 600 in a solution with oxide precursors for a period of time.

An insulating layer 216 is formed on the top surface 208 of the posts 211 and the exposed top portion 218 of the active transport material 214. The insulating layer 216 may be, for example, silicon oxide, aluminum oxide, and magnesium oxide. The structure 600 is immersed in another solution (FIG. 7) to coat a sensitizer material 222 on the active transport material 214. Alternatively, the sensitizer material 122 may be formed by a vapor phase processes. The sensitizer material 122 is a material that converts light for generating electron/hole pairs.

The sensitizer material 222 is preferably organic dye molecules and/or quantum dots, which are sometimes called semiconductor nanocrystallites, whose radii are smaller than the bulk exciton Bohr radius and constitute a class of materials intermediate between molecular and bulk forms of matter. The organic molecules and quantum dots efficiently absorb light, e.g., sun light, and generate electron/hole pairs upon light absorption, they can also be dissolved into various solutions prior to being applied to the structure 600. The sensitizer layer 222 is formed on the active transport layer 214, preferably by, but not limited to, immersing the structure 200 in a solution containing dye complexes and/or quantum dots. The time of immersion can vary from a few minutes to a few days depending on temperature and solution concentration. The dye molecules can be ruthenium complexes where one of the ligands is typically 4,4′-dicarboxy-2,2′-bipyridyl. The quantum dots may be groups of II-VI, III-V, IV, or IV-VI materials, for example, CdS, CdSe, CdTe, ZnS, ZnSe, ZnTe, GaAs, GaP, GaAs, GaSb, HgS, HgSe, HgTe, InAs, InP, InSb, AlAs, AlP, AlSb. Alternative quantum dots that may be used include but are not limited to tertiary microcrystals such as InGaP and ZnSeTe, ZnCdS, ZnCdSe, and CdSeS. Multi-core structures are also possible such as ZnSe/ZnXS/ZnS, where X represents Ag, Sr, Te, Cu, or Mn. The inner most core is made of ZnSe, followed by the second core layer of ZnXS, completed by an external shell made of ZnS.

The structure 700 is then immersed in a solution to coat the sensitizer material 222 with an electrolyte material 224 (FIG. 7). Alternatively, the thin electrolyte layer 224 can also be formed on the sensitizer material using the vapor-phase based processes. The remaining area surrounding the posts 211 is then filled with a material 226 comprised mostly transparent or non-light absorbing conductive electrode material and a small amount of catalysts used for electrochemical reactions. In the preceding steps, any of the active transport material 214, sensitizer material 222, electrolyte material 224, and mixture of transparent conductive electrode material and catalysts 226 forming on the top surface 208 or insulating layer 216 may be removed in any manner known in the industry, such as applying an ion beam at a grazing angle to strike the undesired accumulation. The electrolyte material 224 may be, for example, an electrolyte gel such as the ionic liquid electrolyte gels described by Wang, et al. (Chem. Commun. 2002, 2972-2973), or a polymer gel electrolyte with or without metal oxide nanoparticles fillers such as described by Akhtar et al. (IEEE Proceedings, 2006, 1568-1571), or sol-gel based electrolyte gels such as described by An et al. (Electrochem. Commun. 2006, 8(1), 170-172) and Joseph, et al. (Semiconductor Sci. and Technol. 2006, 21, 697-701). The transparent conductive electrode material 226 may be, for example, indium tin oxide, doped tin oxide or other forms of transparent conducting materials. The catalyst can be platinum, carbon, mixture of platinum and carbon, etc. but preferably is platinum nano-particles.

A capping electrode material 232 is formed over the insulating material 216 and the exposed sensitizer material 222, electrolyte material 224, and conductive electrode material and catalyst 226. The capping electrode material 232 may comprise any conductive material; however, preferably is transparent indium tin oxide. An optional protective layer 234 may be formed over the capping electrode material 232. The protective layer 234 may be, for example, glass or a transparent polymer with anti-reflective property. FIG. 8 is a top view of the structure photovoltaic cell 800 taken along the lines 8-8 of FIG. 7. Although there are only eight photovoltaic cells shown, it is understood there may be many more in one device.

In this exemplary embodiment, the active transport material 214, electrolyte material 224, and mixture of conductive electrode material and catalyst 226, and one or both of the conductive material 202 (including the substrate 204) and the capping electrode material 232 (including the protective layer 234) are formed as a transparent or non-light absorbing material. In operation, the photovoltaic cell is exposed to light, or radiation which may be outside of the visible spectrum. Light enters the structure 800 through either or both the transparent conductive material 202 (including the optional substrate 204) and the capping electrode material 232 (including the optional protective layer 234). This light passes through the conductive electrode material 226 and the electrolyte material 224 to strike the sensitizer material 222, creating electron/hole pairs. The electrons migrate to the conductive material 202 via the active transport material 214, while the holes migrate to the capping electrode material 232 via the electrolyte material 224 and the conductive electrode material 226. The transparent conductive materials 206 and 226 formed in this manner provide a volumetrically interdigitated structure.

In another exemplary embodiment, the substrate 204 or protective layer 234 is opaque so that light and radiation enter only from one side of structure 800.

In yet another exemplary embodiment, the polymer-based electrolyte 224 is replaced by a sacrificial layer of polymer that serves as a spacer layer between the sensitizer material 222 and the transparent conducting electrode material 226. The sacrificial polymer layer provides the space necessary for the electrolyte. Upon completion of the filling the transparent or non-light absorbing conducting electrode material 226 inside the pores, the sacrificial polymer layer is replaced by electrolyte through an exchange process.

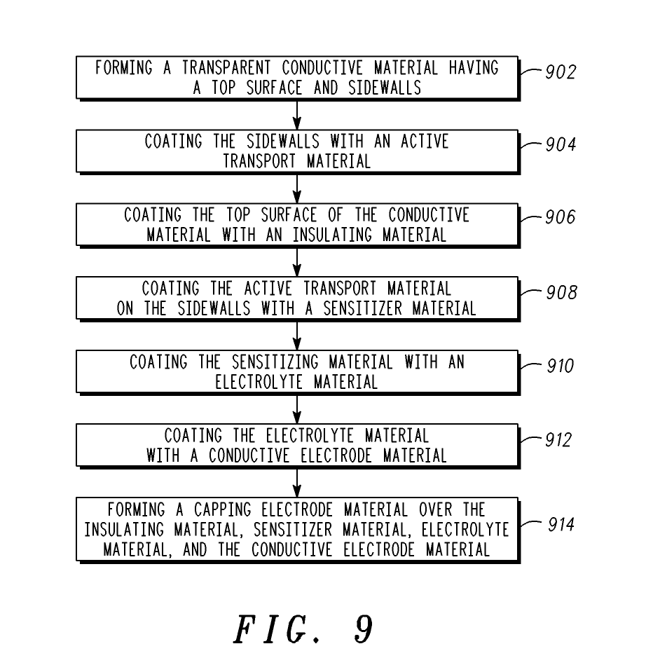

The process of the exemplary embodiments is shown in the flow chart of FIG. 9. A conductive material is formed 902 having a top surface 108, 208 of a conductive material 106, 211 and sidewalls 110, 210. The sidewalls 110, 210 are coated 904 with an active transport material 114, 214. The top surface 108, 208 of the conductive material 106, 206 is coated 906 with an insulating material 116 216 and the active transport material 114, 214 on the sidewall 110, 210 is coated 908 with a sensitizer material 122, 222. The sensitizing material 122, 222 is coated 910 with an electrolyte material 124, 224 and the remaining unoccupied area within the pore 112 or around the post 211 is filled 912 with conductive electrode material mixed with a catalyst 126, 226. A capping electrode material 134, 234 is formed 914 over the top of the structure 900.

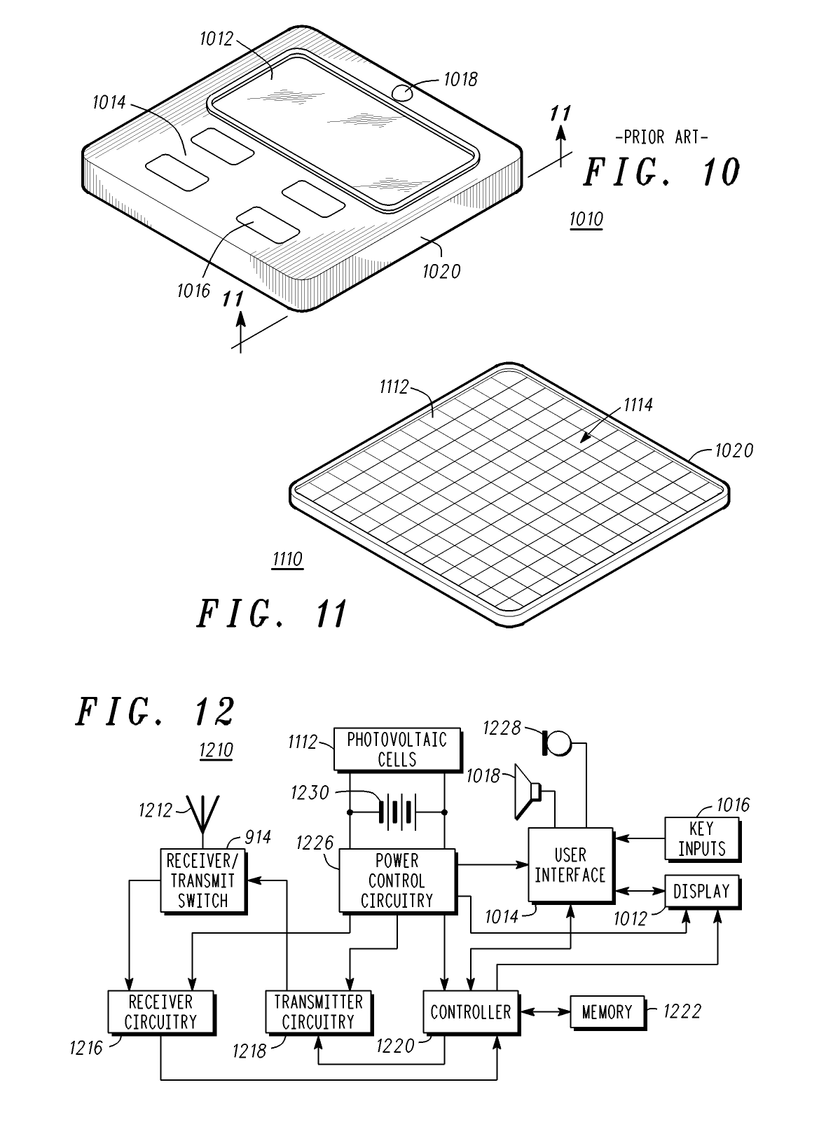

FIG. 10 is an isometric view of an electronic device 1010 comprising a display 1012, a control panel 1014 including a plurality of touch keys 1016, and a speaker 1018, all encased in a housing 1020. The electronic device 1010 may be any type of device requiring a battery as the main source of power or as a back-up source of power. For the exemplary embodiment of a mobile communication device, a Lithium ion battery is preferred; however, any type of rechargeable battery may be charged by the method described herein. Some electronic devices 1010, e.g., a cell phone, may include other elements such as an antenna, a microphone, and a camera (none shown). Furthermore, while the preferred exemplary embodiment of an electronic device is described as a mobile communication device, for example, cellular telephones, messaging devices, and mobile data terminals, other embodiments are envisioned, for example, personal digital assistants (PDAs), computer monitors, gaming devices, video gaming devices, cameras, and DVD players.

FIG. 11 is an isometric view of the electronic device 1110 taken along line 2-2 of FIG. 1. In accordance with an exemplary embodiment, photovoltaic cells 1112 are disposed within the housing 1020 and contiguous to the back side 1114 of the housing 1020.

Referring to FIG. 12, a block diagram of an electronic device 1210 such as a cellular phone is depicted. Though the exemplary embodiment is a cellular phone, the display described herein may be used with any electronic device in which information, colors, or patterns are to be presented through light emission. The portable electronic device 1210 includes an antenna 1212 for receiving and transmitting radio frequency (RF) signals. A receive/transmit switch 1214 selectively couples the antenna 1212 to receiver circuitry 1216 and transmitter circuitry 1218 in a manner familiar to those skilled in the art. The receiver circuitry 1216 demodulates and decodes the RF signals to derive information therefrom and is coupled to a controller 1220 for providing the decoded information thereto for utilization in accordance with the function(s) of the portable communication device 1210. The controller 1220 also provides information to the transmitter circuitry 1218 for encoding and modulating information into RF signals for transmission from the antenna 1212. As is well-known in the art, the controller 1220 is typically coupled to a memory device 1222 and a user interface 1014 to perform the functions of the portable electronic device 1210. Power control circuitry 1226 is coupled to the components of the portable communication device 1210, such as the controller 1220, the receiver circuitry 1216, the transmitter circuitry 1218 and/or the user interface 1014, to provide appropriate operational voltage and current to those components. The user interface 1014 includes a microphone 1228, a speaker 1018 and one or more touch key inputs 1016. The user interface 1014 also includes a display 1012 which could receive touch screen inputs. The photovoltaic cells 812 are coupled to charge the battery 1230 and may be coupled in series or parallel depending on the voltage and current requirements.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. A method of making a plurality of photovoltaic cells for charging a battery of an electronic device, comprising:
forming by a self-assembly process a plurality of photovoltaic cells each having a plurality of interdigitated electrodes coupled between two terminal electrodes coupled to the battery.

2. The method of claim 1 wherein the forming step comprises forming a non-light absorbing conductive material.

3. The method of claim 2 wherein the forming a plurality of photovoltaic cells comprises forming a plurality of fingers having sidewalls and further comprising:
coating an active transport material on the sidewalls;
coating a sensitizer material on the active transport material;
coating an electrolyte material on the sensitizer material; and
forming a conductive electrode material including a catalyst material therein on the electrolyte material.

4. The method of claim 2 wherein the forming a plurality of photovoltaic cells comprises forming a plurality of posts having sidewalls and further comprising:
coating an active transport material on the sidewalls;
coating a sensitizer material on the active transport material;
coating an electrolyte material on the sensitizer material; and
forming a conductive electrode material including a catalyst material therein on the electrolyte material.

5. A method of making a plurality of photovoltaic cells for charging a battery of an electronic device, comprising:
an electrode;
forming a conductive material coupled to the electrode and interdigitated to have a top surface and sidewalls;
coating the sidewalls with an active transport material;
coating the top surface with an insulating material;
coating the active transport material on the sidewall with a sensitizer material;
coating the sensitizing material with an electrolyte material;
coating the electrolyte material to fill the cavity with a conductive electrode material including catalyst materials therein; and
forming a capping electrode material over the insulating material, sensitizer material, electrolyte material, and the conductive electrode material.

6. The method of claim 5 wherein the forming step comprises oxidizing a tin film.

7. The method of claim 5 wherein the forming step comprises forming a tin oxide.

8. The method of claim 5 wherein the coating sidewalls comprises coating with an oxide.

9. The method of claim 5 wherein the coating the active transport material step comprises coating with a plurality of dye molecules.

10. The method of claim 5 wherein the coating the active transport material step comprises coating with a plurality of quantum dots.

11. A portable electronic device, comprising:
a housing, at least a portion of the housing being transparent;
circuitry disposed within the housing and capable of receiving a battery for powering the electronic device; and
a photovoltaic cell coupled to the circuitry for charging the battery and disposed contiguous to the portion of the housing being transparent, the photovoltaic cell comprising interdigitated electrodes.

12. The portable electronic device of claim 11 wherein the interdigitated electrodes comprise an oxidized and treated tin film.

13. The portable electronic device of claim 11 wherein the interdigitated electrodes comprise a tin oxide.

14. The portable electronic device of claim 11 wherein the interdigitated electrodes comprise a conductive material having an oxide coated thereon.

15. The portable electronic device of claim 11 wherein the interdigitated electrodes define a conductive material having an active transport material coated thereon.

16. The portable electronic device of claim 15 further comprising a sensitizer material coated on the active transport material.

17. The portable electronic device of claim 16 wherein the sensitizer material comprises a plurality of dye molecules.

18. The portable electronic device of claim 16 wherein the sensitizer material comprises a plurality of quantum dots.

19. The portable electronic device of claim 16 further comprising an electrolyte material coated on the sensitizer material.

20. The portable electronic device of claim 19 further comprising a conductive electrode material coated on the electrolyte material.
